(19) United States
(12) Patent Application Publication
(10) Pub. No.: US 2009/0034223 A1
(43) Pub. Date: Feb. 5, 2009

(54) Electronic device housing assembly

(76) Inventors: Paul J. Doczy, Cypress, TX (US); Earl W. Moore, Cypress, TX (US); Stacy L. Wolff, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/888,366

(22) Filed: Jul. 31, 2007

(51) Int. Cl. G11C 11/00

(52) U.S. Cl. 361/807

(57) ABSTRACT

An electronic device, comprising a housing assembly comprising a wall and stiffener, the stiffener having a plurality of apertures and bonded to at least a portion of the wall.

### BACKGROUND

Housing for electronic devices are generally formed of molded plastic. However, plastic housings, although lightweight, are not extremely durable and can crack and/or break apart. Some housing are made from a stiffer material, such as magnesium. However, such housing are costly and tend to increase the overall weight of the electronic device.

### BRIEF DESCRIPTION OF THE DRAWINGS

FIG. 1 illustrates an electronic device in which an embodiment of a housing assembly is employed to advantage;

FIG. 2 illustrates an exploded assembly view of a display member of the electronic device of FIG. 1 in which an embodiment of the housing assembly is employed to advantage; and

FIG. 3 is a cross-sectional view of the housing assembly of FIG. 1 taken along line 3-3 of FIG. 1.

### DETAILED DESCRIPTION OF THE DRAWINGS

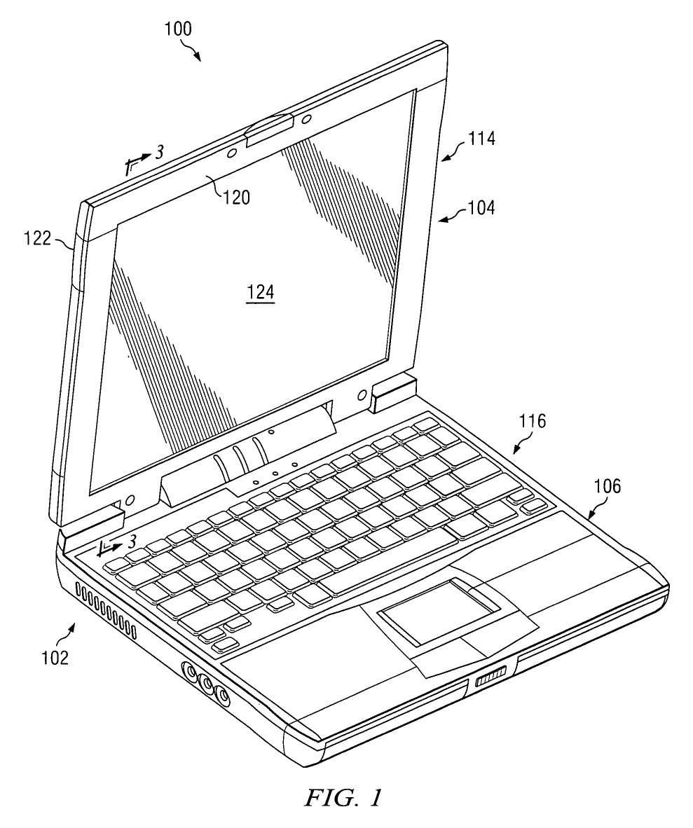

FIG. 1 illustrates an electronic device 100 in which an embodiment of a housing assembly 114 is employed to advantage. In the illustrative embodiment, electronic device 100 is a laptop or notebook computer 102. However, it should be understood that electronic device 100 may also be embodied as a cellular telephone, a personal digital assistant (PDA), a tablet computer, a gaming device, a desktop computer, a television set, or any other type of electronic device. In the illustrated embodiment, electronic device 100 comprises a display member 104 rotatably coupled to a base member 106. Display member 104 comprises housing assembly 114 and base member 106 comprises a housing assembly 116 for housing and/or supporting one or more components of electronic device 100. For example, in the illustrative embodiment, housing assembly 114 comprises a front wall 120 and a back wall 122 and supports a display screen 124. However, it should be understood that a greater or fewer quantity of components having various shapes and/or sizes may be used to form housing assemblies 114 and/or 116.

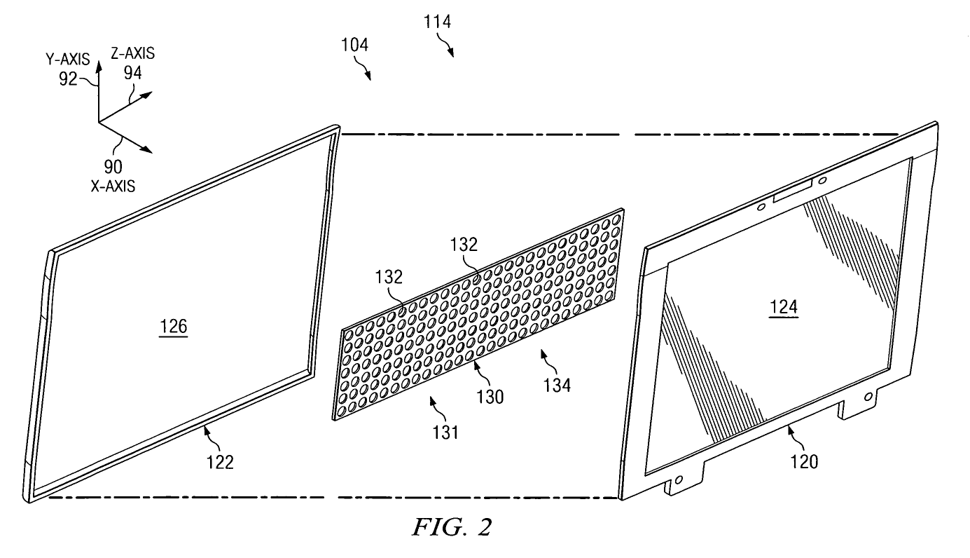

FIG. 2 illustrates an exploded assembly view of display member 104 for electronic device 100 in which an embodiment of housing assembly 114 is employed to advantage. It should be noted that the configuration of housing assembly 114 for display member 104 as described in FIG. 2 can also be employed in housing assembly 116 for base member 106 of FIG. 1. In FIG. 2, front wall 120 comprises an opening to facilitate viewing of display screen 124 therethrough. Front wall 120 and back wall 122 may be formed of plastic, metal, or any combination thereof. In some embodiments, housing assembly 114 comprises a stiffener 130 disposed between front wall 120 and back wall 122. In some embodiments, stiffener 130 comprises a perforated panel 131. In the illustrated embodiment, stiffener 130 is coupled to an internal surface 126 of back wall 122. An “internal surface” is defined as a surface disposed on the inside of a housing assembly (e.g., housing assembly 114). It should be noted, however, that stiffener 130 can also be coupled to an external surface of front wall 120 and/or back wall 122. An “external surface” is defined as a surface disposed on the outside of a housing assembly (e.g., housing assembly 114). In the illustrated embodiment, stiffener 130 is a substantially flat sheet perforated with a plurality of apertures 132 in a honeycomb-like pattern 134. Apertures 132 can be completely and/or substantially permeating (e.g., through-holes) or semi-permeable (e.g., partial through-holes). It should be noted, however, that apertures 132 are not limited to a particular pattern and can comprise any number and/or combination of patterns, sizes, and/or shapes (e.g., square, hexagon, etc.). For example, some apertures 132 can be larger in size than other apertures 132, and some apertures 132 can be one shape while other apertures 132 are another shape. Stiffener 130 is also not limited to the number of apertures 132 and can comprise a greater or fewer number of total apertures 132. It should also be understood, however, that apertures 132 may be distributed in selected portions of stiffener 130 (e.g., only in the bottom half, top half, middle, sides, etc.). Apertures 132 may also be entirely omitted from stiffener 130.

In some embodiments, stiffener 130 comprises a material (aluminum, stainless steel, magnesium, titanium, other type of metal, plastic, or any combination thereof selected to add stiffness and/or increased ability to withstand a shock event (e.g., an object hitting display module 104, electronic device 100 being dropped, etc.). In some embodiments, the material and/or pattern selected for stiffener 130 is balanced with the overall weight (e.g., mass) of the material and the number, size, and/or shape of apertures 132. Furthermore, in some embodiments, stiffener 130 can extend over substantially all or a portion of the periphery of front wall 120 and/or back wall 122. Moreover, in some embodiments, stiffener 130 can be sized and/or located to provide stiffness along a particular direction and/or axis (e.g., x-axis 90, y-axis 92, z-axis, 94) of housing assembly 114. For example, in one embodiment, stiffener 130 can be configured to provide increased lateral stiffness along x-axis 90 and/or longitudinal stiffness along y-axis 92 of housing assembly 114.

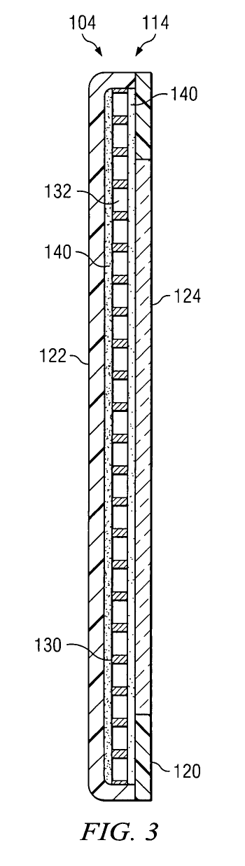

FIG. 3 is a cross-sectional view of housing assembly 114 for display member 104 taken along line 3-3 of FIG. 1. In the illustrated embodiment, at least a portion of front wall 120 and back wall 122 are both coupled to stiffener 130 using a bonding mechanism 140. Bonding mechanism 140 is any means that enables front wall 120 and/or back wall 122 to be coupled to stiffener 130. In some embodiments, bonding mechanism 140 comprises an adhesive for adhering stiffener 130 to back wall 122 such as, but not limited to, an epoxy adhesive, double-sided tape, etc. which may be applied with or without heating, pressure, etc. Other examples of bonding mechanisms 140 include, but are not limited to, welding, screwing, fastening, press fitting, etc. In some embodiments, housing assembly 114 may omit bonding mechanism 140 but, instead, wrap front wall 120 and/or back wall 122 around stiffener 130 (e.g., molding stiffener 130 into front wall 120 and/or back wall 122 such that at least a substantial portion of stiffener 130 is folded into front wall 120 and/or back wall 122). A portion of stiffener 130 may also contain an opening or other access area to accommodate other components of electronic device 100 disposed between walls 120 and 122.

Thus, embodiments of electronic device 100 may be manufactured by providing stiffener 130 having a plurality of apertures 132 and bonding stiffener 130 to a wall (e.g., wall 120, 122, etc.) of electronic device 100. Electronic device 100 may also be manufactured by bonding stiffener 130 to an internal surface of the wall. Electronic device 100 may also be manufactured by providing stiffener 130 having a plurality of permeating apertures 132. Electronic device 100 may also be manufactured by configuring the plurality of apertures 132 to form a honeycomb-like pattern 134. Electronic device 100 may also be manufactured by extending the stiffener 130 substantially over at least one dimension of the wall. Electronic device 100 may also be manufactured by bonding stiffener 130 to a back wall 122 of display member 104 of electronic device 100. Electronic device 100 may also be manufactured by bonding stiffener 130 to a portion of at least two walls of electronic device 100. Electronic device 100 may also be manufactured by adhesively bonding stiffener 130 to the wall.

Thus, embodiments of electronic device 100 provide a housing assembly 114 with increased stiffness and ability to withstand shock events experienced by electronic device 100. Embodiments of electronic device 100 reduce the overall weight (e.g., mass) of electronic device 100 without sacrificing durability, thereby reducing costs associated with shipping electronic device 100 while increasing consumer appeal for long-lasting, light weight electronic device 100.

1. An electronic device, comprising:
a housing assembly comprising a wall and stiffener, the stiffener having a plurality of apertures and bonded to at least a portion of the wall.

2. The electronic device of claim 1, wherein the stiffener is bonded to an internal surface of the wall.

3. The electronic device of claim 1, wherein the plurality of apertures comprise permeating apertures.

4. The electronic device of claim 1, wherein the plurality of apertures form a honeycomb-like pattern.

5. The electronic device of claim 1, wherein the stiffener extends substantially over at least one dimension of the wall.

6. The electronic device of claim 1, wherein the wall comprises a back wall of a display member of the electronic device.

7. The electronic device of claim 1, wherein the stiffener is bonded to at least a portion of at least two walls of the electronic device.

8. The electronic device of claim 1, wherein the stiffener is adhesively bonded to the wall.

9. A method of manufacturing an electronic device, comprising:
providing a stiffener having a plurality of apertures; and
bonding the stiffener to a wall of the electronic device.

10. The method of claim 9, further comprising bonding the stiffener to an internal surface of the wall.

11. The method of claim 9, further comprising providing the stiffener having a plurality of permeating apertures.

12. The method of claim 9, further comprising configuring the plurality of apertures to form a honeycomb-like pattern.

13. The method of claim 9, further comprising extending the stiffener substantially over at least one dimension of the wall.

14. The method of claim 9, further comprising bonding the stiffener to a back wall of the display member of the electronic device.

15. The method of claim 9, further comprising bonding the stiffener to a portion of at least two walls of the electronic device.

16. The method of claim 9, further comprising adhesively bonding the stiffener to the wall.

17. An electronic device, comprising:
a display member rotably coupled to a base member, the display member having at least one wall; and
a stiffener bonded to the at least one wall.

18. The electronic device of claim 17, when the stiffener is bonded to an internal surface of the at least one wall.

19. The electronic device of claim 17, wherein the stiffener comprises a perforated panel.

20. The electronic device of claim 17, wherein the stiffener is adhesively bonded to the at least one wall.
